(19) United States
(12) Patent Application Publication
(10) Pub. No.: US 2008/0112138 A1
(43) Pub. Date: May 15, 2008

(54) FASTENER AND HEAT DISSIPATION MODULE HAVING THE SAME

(75) Inventor: Hung-Ming Lin, Taipei (TW)

Correspondence Address: J C PATENTS, INC., 4 VENTURE, SUITE 250, IRVINE, CA, 92618, US

(73) Assignee: AMA PRECISION INC., Taipei (TW)

(21) Appl. No.: 11/873,991

(22) Filed: Oct. 17, 2007

(30) Foreign Application Priority Data
Nov. 13, 2006 (TW) 95141900

(51) Int. Cl. H05K 7/20

(52) U.S. Cl. 361/704; 24/453

(57) ABSTRACT

A fastener including a body, multiple hooks, a pressing structure, and a connecting rod is provided. The body has a first end, a second end, and a through hole passing through from the first end to the second end. The hooks are provided in the first end, and the pressing structure is provided at the second end. The connecting rod is provided through the through hole. One end of the connecting rod is connected to the pressing structure and the other end thereof has an expansion portion. The hooks are suitable to insert in a hole of a plate when the expansion portion is provided outside the hooks. The hooks inserted in the hole are expanded outward to be fastened with the plate when the pressing structure drives the connecting rod to make the expanded portion move into the hooks. A heat dissipation module having the fastener is also provided.

### CROSS-REFERENCE TO RELATED APPLICATION

This application claims the priority benefit of Taiwan application serial no. 95141900, filed on Nov. 13, 2006. All disclosure of the Taiwan application is incorporated herein by reference.

### BACKGROUND OF THE INVENTION

1. Field of the Invention

The invention relates to a fastener and, more particularly, to a fastener suitable to assemble a heat dissipation module on a plate, and a heat dissipation module with the fastener.

2. Description of the Related Art

Recently, with the development of the science and technology, the calculation speed of, for example, a central processing unit (CPU) in a computer device is continuously increased, and therefore the heat generation power is also continuously increased. To avoid the temporary or permanent invalidation because of the overheating of the CPU, the computer device needs a sufficient heat dissipation ability to make the CPU work normally. To dissipate the heat produced by the CPU working in a high speed, and enable the CPU to work in a normal state, a heat dissipation module is directly provided on the CPU (or a chip generating heat) in the prior art, and the heat generated by the CPU can be dissipated to the environment by the heat dissipation module.

FIG. 1A is a schematic diagram showing a conventional heat dissipation module provided on a heat source. FIG. 1B is an exploded diagram showing the heat dissipation module and the heat source shown in FIG. 1A. Please refer to FIG. 1A and FIG. 1B simultaneously. A conventional heat dissipation module 100 includes a heat sink 110 and a plurality of spring screws 120 provided on the heat sink 110, and the user can turn the spring screws 120 by a fastening tool such as a screwdriver to make the spring screws 120 be fastened in the holes 12 around the heat source 10. Therefore, the heat sink 110 can be firmly provided on the heat source 10 to dissipate the heat for the heat source 10.

In the process of assembling the heat sink 110 on the heat source 10, the user needs to use an additional fastening tool to fasten the spring screws 120 in the holes 12 to make the heat sink 110 be closely against the heat source 10, so that it will take more assembling time in the prior art. Certainly, when the heat sink 110 needs to be disassembled from the heat source 10 to be repaired or cleaned, it will also take more time. Moreover, if there is no proper assembling or disassembling tool, the user can not assemble the heat dissipation module 100 on the heat source 10, or disassemble the heat dissipation module 100 from the heat source 10, and it causes inconvenience.

In other prior art, the heat sink can be assembled on the heat source by a plurality of push pins. In the process of assembling the heat sink on the heat source, the user only needs to press the push pins provided on the heat sink, the push pins can be directly fastened in the holes around the heat source to save the assembling time of the heat dissipation module. However, in the process of disassembling the heat sink from the heat source, the user still needs to use an additional tool to relieve the fastening relationship between the push pins and the holes. Therefore, the user can not quickly disassemble the heat sink from the heat source.

### BRIEF SUMMARY OF THE INVENTION

The objective of the invention is to provide a fastener, which has a simple mode of operation.

Another objective of the invention is to provide a heat dissipation module, which can be quickly assembled on or disassembled from the heat source by the fastener.

To achieve the above or other objectives, the invention provides a fastener, which is assembled at a heat sink and suitable to be fastened at a hole of a plate. The fastener includes a body, a plurality of hooks, a pressing structure, and a connecting rod. The body has a first end, a second end, and a through hole passing through from the first end to the second end. The hooks are provided at the first end, and the pressing structure is provided at the second end. Furthermore, the connecting rod is provided through the through hole, one end of the connecting rod is connected to the pressing structure, and the other end has an expansion portion. The hooks are suitable to insert in a hole of a plate when the expansion portion is provided outside the hooks. When the pressing structure drives the connecting rod to make the expansion portion move into the hooks, the hooks inserted in the hole are expanded outward by the act of the expansion portion, so that the hooks can be fastened at the plate.

In one embodiment of the invention, the hooks and the body are integrally formed.

In one embodiment of the invention, the pressing structure includes a pressing part and an axle. The pressing part has a plurality of pivot holes, the axle is pivotally provided in the pivot holes along a first axis, and the axle is connected to the connecting rod.

In one embodiment of the invention, the first axis is vertical to the extending direction of the connecting rod.

In one embodiment of the invention, the pressing part is suitable to move around the body along a second axis to drive the axle to move along the extending direction of the connecting rod.

In one embodiment of the invention, the relative motion of the pressing part and the axle will drive the expansion portion to move along the extending direction of the connecting rod.

The invention further provides a heat dissipation module, which is suitable to dissipate heat for a heat source on a plate. The heat dissipation module according to the invention includes a heat sink and a plurality of fasteners described above, and the fasteners are provided on the heat sink. The fasteners are suitable to be fastened at the holes around the heat source to fasten the heat sink on the heat source.

In a preferred embodiment of the invention, the heat dissipation module has a heat sink and a plurality of fasteners provided on the heat sink, and the heat sink can be fastened on the heat source by the fasteners to dissipate the heat for the heat source. The user only needs to press the pressing structure of the fasteners, the expansion portion of the connecting rod can move into the plurality of hooks. The hooks inserted in the hole are expanded outward with the action of the expansion portion and fastened with the plate closely, and the heat sink can be fastened on the heat source firmly. On the other hand, when the user turns the pressing structure to the original position, the expansion portion can withdraw from the hooks, and the hooks can get rid of the action of the expansion portion. That is, the hooks can go back to the position where they do not expand outward, and the heat sink will be easily disassembled from the heat source.

In the preferred embodiment of the invention, simple interlocking relationship is used to enable the hooks of the fastener to be fastened at the holes of the plate to save the time used to assemble the heat sink on the heat source. Certainly, in the preferred embodiment of the invention, the interlocking relationship can also be used to quickly relieve the fastening relationship between the hooks and the plate, so that a user can easily disassemble the heat sink from the heat source without additional auxiliary tools.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1A is a schematic diagram showing a conventional heat dissipation module provided on a heat source.

FIG. 1B is an exploded diagram showing the heat dissipation module and the heat source shown in FIG. 1A.

FIG. 2A is an exploded diagram showing a heat dissipation module and a heat source according to a preferred embodiment of the invention.

FIG. 2B is a schematic diagram showing when the heat dissipation module shown in FIG. 2A is assembled on the heat source.

FIG. 3A is an enlarged diagram showing the fastener in FIG. 2A.

FIG. 3B is an exploded diagram showing the fastener shown in FIG. 3A.

FIG. 4 is a schematic diagram showing the pressing part in FIG. 3A after it has been pressed.

FIG. 5A is a part section diagram showing the heat dissipation module provided on the heat source in FIG. 2B.

FIG. 5B is a section diagram showing the fastener in FIG. 5A fastened at the holes around the heat source.

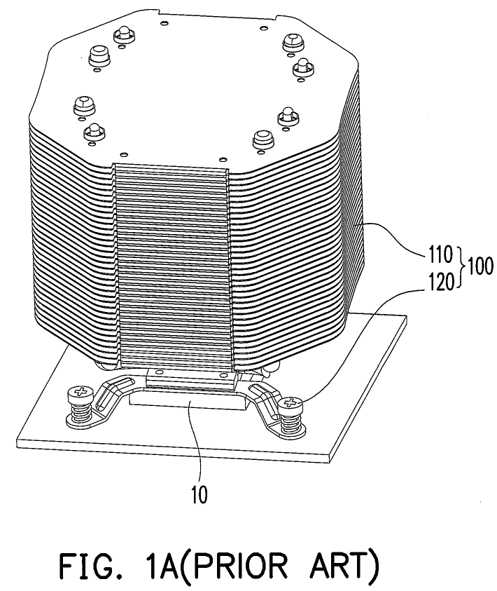

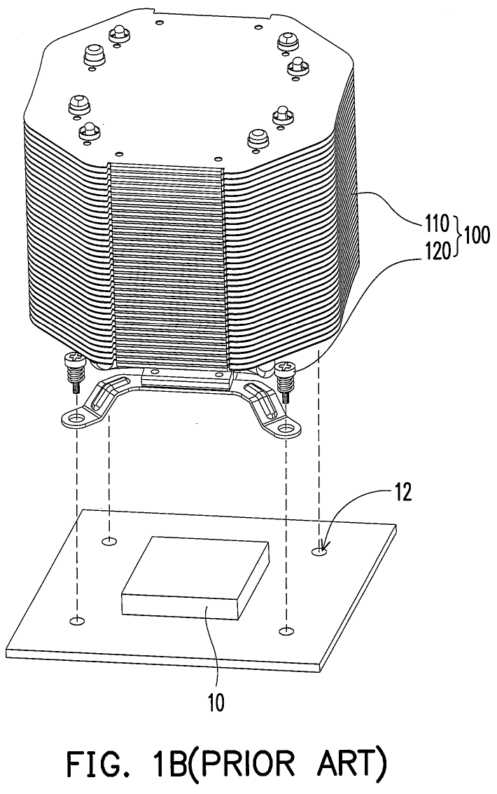

### DETAILED DESCRIPTION OF THE EMBODIMENTS

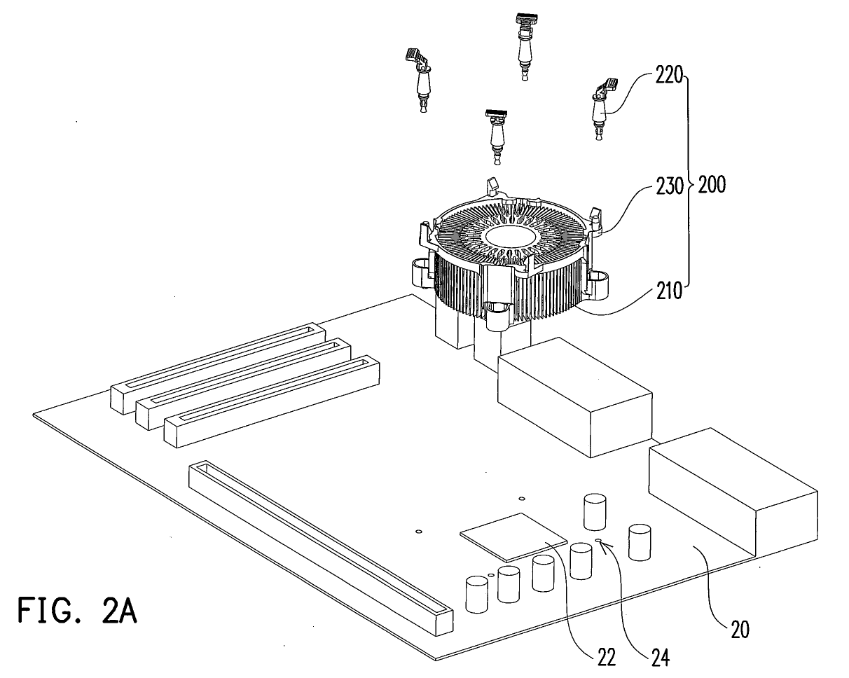

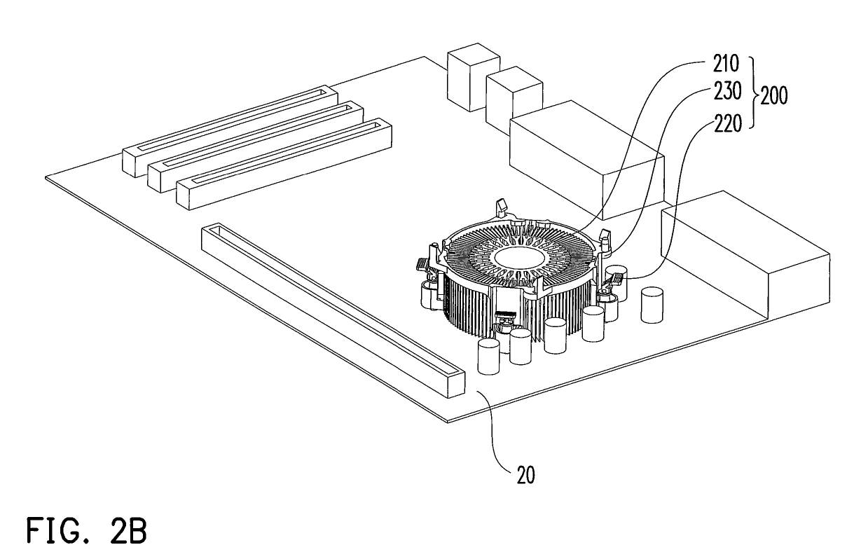

FIG. 2A is an exploded diagram showing a heat dissipation module and a heat source according to a preferred embodiment of the invention, and FIG. 2B is a schematic diagram showing the heat dissipation module in FIG. 2A assembled on the heat source, wherein the fasteners 220 in FIG. 2B has not been fastened at the holes 24 around the heat source 22. Please refer to FIG. 2A and FIG. 2B at the same time. The heat dissipation module 200 in the embodiment is suitable to dissipate heat for the heat source 22 on a plate 20 to make the heat source 22 work in a normal state. In the embodiment, the plate 20 may be a motherboard, and the heat source 22 may be a central processing unit (CPU).

In the embodiment, the heat dissipation module 200 includes a heat sink 210 and a plurality of fasteners 220. The heat sink 210 is suitable to be provided on the heat source 22, and the fasteners 220 can be provided on the heat sink 210 by a fastening holder 230. The fasteners 220 are suitable to be fastened at a plurality of holes 24 around the heat source 22, so that the heat sink 210 can be fastened to the heat source 22 firmly to dissipate the heat of for the heat source 22. Furthermore, a fan can be provided on the fastening holder 230, and the active air stream generated by the fan can remove the heat that the heat source conducts to the heat sink to increase the heat dissipation efficiency of the heat sink 210. Certainly, in other preferred embodiment, the fasteners 220 also can be directly provided on the heat sink 210, and there is no limitation in this invention. Moreover, the embodiment will describe the structure of the fasteners 220 and how the fasteners 220 are fastened at the holes 24 around the heat source 22 hereinbelow.

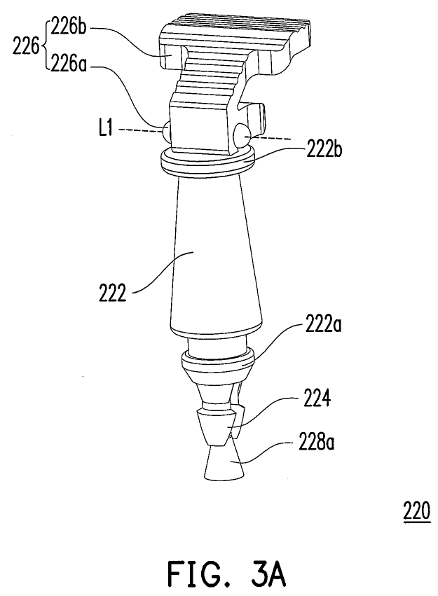

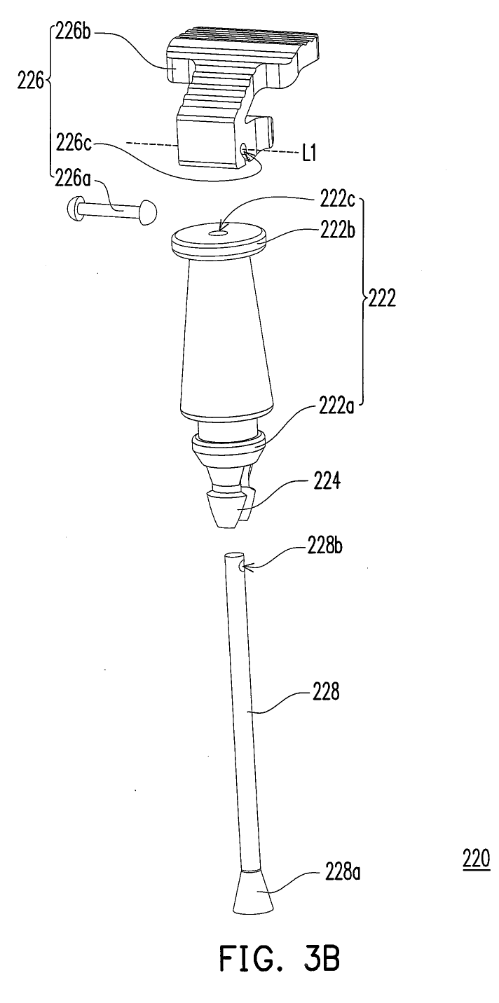

The embodiment illustrates the inner structure of the fasteners 220 and the interlocking relationship between the inner elements. Referring to FIG. 3A and FIG. 3B, FIG. 3A is an enlarged diagram showing the fastener in FIG. 2A, and FIG. 3B is an exploded diagram showing the fastener in FIG. 3A. In FIG. 3A and FIG. 3B, the fastener 220 of the embodiment includes a body 222, a plurality of hooks 224, a pressing structure 226, and a connecting rod 228. In the embodiment, the body 222 has a first end 222a, a second end 222b, and a through hole 222c passing through from the first end 222a to the second end 222b. The hooks 224 are provided at the first end 222a, and the connecting rod 228 is provided through the through hole 222c. In the embodiment, the hooks 224 and the body 222 are integrally formed.

Furthermore, in the embodiment, one end of the connecting rod 228 is connected to the pressing structure 226 which is provided on the second end 222b, and the other end of the connecting rod 228 has an expansion portion 228a. In detail, the pressing structure 226 of the embodiment includes an axle 226a and a pressing part 226b with a plurality of pivot holes 226c, wherein the axle 226a is pivotally provided in the pivot holes 226c along a first axis L1 (the first axis L1 is vertical to the extending direction of the connecting rod 228). Therefore, the connecting rod 228 can be connected to the pressing part 226b by the axle 226a (the connecting rod 228 has, for example, a hole 228b, and the axle 226a can be provided through the hole 228b).

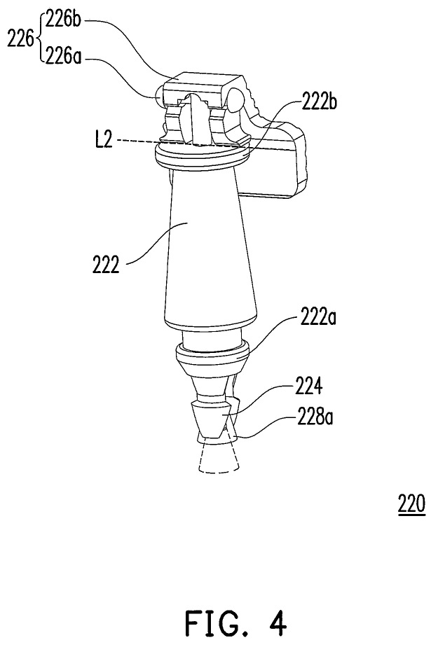

As described above, when the pressing part 226b is pressed, the pressing part 226b will move around the body 222 along a second axis L2 (Please referring to FIG. 4 which is a schematic diagram showing the pressing part in FIG. 3A after it has been pressed), and drive the axle 226a to move along the extending direction of the connecting rod 228 simultaneously. The relative motion of the pressing part 226b and the axle 226a drives the expansion portion 228a to move along the extending direction of the connecting rod 228 upward and move into the hooks 224, the hooks 224 will be expanded outward with the action of the expansion portion 228a. Certainly, when the user turns the pressing part 226b to the original position, the expansion portion 228a can withdraw from the hooks 224, and the hooks 224 can get rid of the action of the expansion portion 228a. That is, the hooks 224 can go back to the position where they do not expand outward.

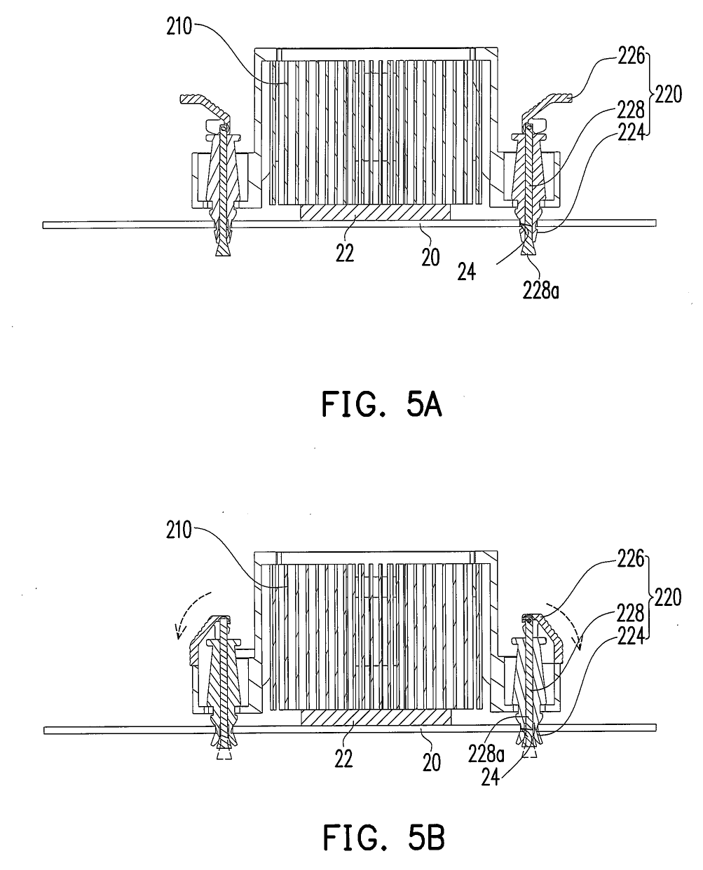

Then it illustrates how the fastener 220 can be fastened at the holes 24 around the heat source 22 hereinbelow. Referring to FIG. 5A and FIG. 5B, FIG. 5A is a part section diagram showing the heat dissipation module provided on the heat source in FIG. 2B. FIG. 5B is a section diagram showing the fastener in FIG. 5A fastened at the holes around the heat source. First referring to FIG. 5A, when the pressing structure 226 has not been pressed, the expansion portion 228a of the connecting rod 228 is outside of the hooks 224, therefore the hooks 224 may be inserted into the hole 24 of the plate 20 successfully. In addition, when the pressing structure 226 has been pressed (as showing in FIG. 5B), the pressing structure 226 can drive the connecting rod 228 to move upwards, to make the expansion portion 228a move into the plurality of hooks 224, and the hooks 224 will be expanded outward and fastened at the holes 24 of the plate 20. Therefore, the heat sink 210 provided on the heat source 22 can be assembled on the heat source 22 by the fasteners 220 firmly to dissipate the heat for the heat source 22.

On the other hand, when the user wants to disassemble the heat sink 210 from the heat source 22, the user only needs to turn the pressing structure 226 to the original position, and the expansion portion will withdraw from the hooks 224. Therefore, the hooks 224 will get rid of the action of the expansion portion 228a (the hooks 224 will go back to the position where they do not expand outward), and the heat dissipation module 200 can be easily disassembled from the heat source 22.

In summary, the heat dissipation module in the preferred embodiment of the invention mainly includes a heat sink and a plurality of fasteners provided on the heat sink, wherein the heat sink is fastened on the heat source by these fasteners to dissipate the heat for the heat source. In the embodiment, the expansion portion of the connecting rod can be driven to move into the hooks only by pressing the pressing structure of the fasteners, so that the hooks will be expanded outward and fastened at the holes of the plate, and the heat sink will be firmly provided on the heat source (the heat sink can be closely contacted with the heat source). Similarly, when the user wants to disassemble the heat sink from the heat source, the user only needs to turn the pressing structure to the original position, and the expansion portion of the connecting rod will withdraw from the hooks to relieve the fastening relationship between the hooks and the plate, therefore the heat sink will be easily disassembled from the heat source.

Compared with the prior art, the fasteners in the preferred embodiment of the invention can be simply and quickly fastened at the hole of the plat without additional auxiliary tools. That is, the heat sink can be quickly assembled on the heat source by the fasteners of the invention to save the assembling time. Furthermore, the user can relieve the fastening relationship between the hooks and the plate only by adjusting the position of the pressing structure of the fastener to the original position, and the heat sink can be dissembled from the heat source without additional auxiliary tools.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A fastener suitable to be assembled at a heat sink and suitable to be fastened at a hole of a plate, the fastener comprising:
a body having a first end, a second end, and a through hole which passes through from the first end to the second end;
a plurality of hooks provided at the first end;
a pressing structure provided at the second end; and
a connecting rod provided through the through hole, wherein one end of the connecting rod is connected to the pressing structure, and the other end of the connecting rod has an expansion portion;
wherein the hooks are suitable to insert in the hole when the expansion portion is provided outside the hooks, and the hooks inserted in the hole are expanded outward with the action of the expansion portion to be fastened at the plate when the pressing structure drives the connecting rod to make the expansion portion move into the hooks.

2. The fastener according to claim 1, wherein the hooks and the body are integrally formed.

3. The fastener according to claim 1, wherein the pressing structure comprises a pressing part and an axle, the pressing part has a plurality of pivot holes, and the axle is pivotally provided at the pivot holes along a first axis, and the axle is connected to the connecting rod.

4. The fastener according to claim 3, wherein the first axis is vertical to the extending direction of the connecting rod.

5. The fastener according to claim 4, wherein the pressing part is suitable to move around the body along a second axis to drive the axle to move along the extending direction of the connecting rod.

6. The fastener according to claim 5, wherein the relative motion of the pressing part and the axle drives the expansion portion to move along the extending direction of the connecting rod.

7. A heat dissipation module suitable to dissipate heat for a heat source on a plate, wherein a plurality of holes is around the heat source, the heat dissipation module comprising:
a heat sink;
a plurality of fasteners provided at the heat sink, wherein the fasteners are suitable to be fastened at the holes to fasten the heat sink on the heat source, and each of the fastener comprises:
a body having a first end, a second end, and a through hole which passes through from the first end to the second end;
a plurality of hooks provided at the first end;
a pressing structure provided at the second end; and
a connecting rod provided through the through hole, wherein one end of the connecting rod is connected to the pressing structure, and the other end of the connecting rod has an expansion portion;
wherein the hooks are suitable to insert in each of the holes when the expansion portion is provided outside the hooks, and the hooks inserted in each of the holes are expanded outward with the action of the expansion portion to be fastened at the plate when the pressing structure drives the connecting rod to make the expansion portion move into the hooks.

8. The heat dissipation module according to claim 7, wherein the hooks and the body are integrally formed.

9. The heat dissipation module according to claim 7, wherein the pressing structure comprises a pressing part and an axle, and the pressing part has a plurality of pivot holes, while the axle is pivotally provided at the pivot holes along a first axis, and the axle is connected to the connecting rod.

10. The heat dissipation module according to claim 9, wherein the first axis is vertical to the extending direction of the connecting rod.

11. The heat dissipation module according to claim 10, wherein the pressing part is suitable to move around the body along a second axis to drive the axle to move along the extending direction of the connecting rod.

12. The heat dissipation module according to claim 11, wherein the relative motion of the pressing part and the axle drives the expansion portion to move along the extending direction of the connecting rod.
